(19) United States
(12) Patent Application Publication
(10) Pub. No.: US 2026/0101700 A1
(43) Pub. Date: Apr. 9, 2026

(54) PEELING METHOD, WAFER PRODUCTION METHOD, AND BONDED WAFER

(71) Applicant: DISCO CORPORATION, Tokyo (JP)

(72) Inventor: Akira MIZUTANI, Tokyo (JP)

(21) Appl. No.: 19/312,981

(22) Filed: Aug. 28, 2025

(30) Foreign Application Priority Data
Oct. 7, 2024 (JP) 2024-175898

(51) Int. Cl. H01L 21/67; B23K 26/53; H01L 21/304; B23K 101/40

(52) U.S. Cl. CPC H10P 72/0428; B23K 26/53; H10P 52/00; B23K 2101/40

(57) ABSTRACT

A peeling method of the present invention includes: a laser processing step of forming a processing layer in an SiCN film by applying, to a bonded wafer which includes a first wafer and a second wafer and in which a surface of the first wafer in which a first device and a first bonding film are formed on the surface is bonded to a surface of the second wafer in which a second bonding film including the SiCN film is formed on the surface via the first bonding film and the second bonding film, laser light having a wavelength transmissive to the second wafer from the second wafer side; and a peeling step of peeling the second wafer from the bonded wafer at the processing layer.

### CROSS-REFERENCE TO RELATED APPLICATION

This application claims priority from Japanese Patent Application No. 2024-175898 filed with the Japan Patent Office on October 7, 2024, the entire content of which is hereby incorporated by reference.

### BACKGROUND ART

### 1. Technical Field

The present invention relates to a peeling method, a wafer production method, and a bonded wafer.

### 2. Related Art

According to a technology disclosed by Japanese Unexamined Patent Publication No. 2024-062595, a stacked wafer is produced in such a way that devices on one of two wafers are transferred to the other wafer by bonding the two wafers and then removing the one wafer by grinding. A s a result of the grinding, the one wafer remains with the thickness of 10 μm. The stacked wafer is therefore thick.

Meanwhile, Japanese Unexamined Patent Publication No. 2021-006352 discloses a method of peeling one of two wafers by forming a processing layer in an insulating film provided between the two wafers, by means of laser light having a wavelength transmissive through the one wafer.

### SUMMARY

According to the technology of Japanese Unexamined Patent Publication No. 2021-006352, however, the insulating film is required to be thick in order to avoid damage to devices, and this hinders the productivity.

An object of the present invention is therefore to suppress damage to devices caused by through light passing through an insulating film provided between a wafer and the devices, when a processing layer is formed in the insulating film by laser light.

A peeling method of the present invention (present peeling method) includes: a laser processing step of forming a processing layer in an SiCN film by applying, to a bonded wafer which includes a first wafer and a second wafer and in which a surface of the first wafer in which a first device and a first bonding film are formed on the surface is bonded to a surface of the second wafer in which a second bonding film including the SiCN film is formed on the surface via the first bonding film and the second bonding film, laser light having a wavelength transmissive to the second wafer from the second wafer side; and a peeling step of peeling the second wafer from the bonded wafer at the processing layer.

The present peeling method may be arranged so that the second bonding film of the second wafer includes a second device formed on the SiCN film.

The present peeling method may be arranged so that the second bonding film of the second wafer includes a metal film formed between the SiCN film and the second device.

The present peeling method may be arranged so that the second bonding film of the second wafer includes an SiO₂ film or an SiN film formed between the SiCN film and the metal film.

The present peeling method may be arranged so that the wavelength of the laser light falls within a range of 1064 to 5000 nm, and a range of a dose amount of the laser light is 0.1389 J/mm² or more and 0.7 J/mm² or less.

A wafer production method of the present invention includes: preparing a bonded wafer which includes a first wafer and a second wafer and in which a surface of the first wafer in which a first device and a first bonding film are formed on the surface is bonded to a surface of the second wafer in which a second bonding film including the SiCN film is formed on the surface via the first bonding film and the second bonding film; and performing the peeling method according to claim 1 for the bonded wafer.

A bonded wafer of the present invention (present bonded wafer) includes: a first wafer in which a first device and a first bonding film are formed on a surface; and a second wafer in which a second bonding film is formed on a surface, the surfaces of the first wafer and the second wafer being bonded to each other via the first bonding film and the second bonding film, and the second bonding film including an SiCN film formed on the surface of the second wafer and a second device formed on the SiCN film.

The present bonded wafer may be arranged so that the second bonding film of the second wafer includes a metal film formed between the SiCN film and the second device.

The present bonded wafer may be arranged so that the second bonding film of the second wafer includes an SiO₂ film or an SiN film formed between the SiCN film and the metal film.

According to the present peeling method, the second bonding film provided between the first wafer and the second wafer includes the SiCN film, and in the laser processing step, the processing layer is formed in the SiCN film by applying the laser light to the SiCN film from the second wafer side. Because the SiCN film absorbs the laser light well, the laser light does not easily pass through the SiCN film. It is therefore possible to suppress the destruction of the devices which are fine pitch layers provided below the SiCN film due to the application of the laser light (through light) having passed through the SiCN film, without requiring increase in thickness of the SiCN film.

### BRIEF DESCRIPTION OF THE DRAWINGS

FIG. 1 is a cross-sectional view illustrating a preparation step.

FIG. 2 is a cross-sectional view illustrating a wafer bonding step.

FIG. 3 is a cross-sectional view illustrating a laser processing step.

FIG. 4 is a cross-sectional view illustrating a peeling step.

FIG. 5 is a cross-sectional view illustrating another preparation step.

FIG. 6 is a cross-sectional view illustrating another wafer bonding step.

FIG. 7 is a cross-sectional view illustrating another laser processing step.

FIG. 8 is a cross-sectional view illustrating another peeling step.

FIG. 9 is a cross-sectional view illustrating still another preparation step.

FIG. 10 is a cross-sectional view illustrating still another wafer bonding step.

FIG. 11 is a cross-sectional view illustrating still another laser processing step.

FIG. 12 is a cross-sectional view illustrating still another peeling step.

FIG. 13 is a cross-sectional view illustrating yet another preparation step.

FIG. 14 is a cross-sectional view illustrating yet another wafer bonding step.

FIG. 15 is a cross-sectional view illustrating a grinding step.

FIG. 16 is a cross-sectional view illustrating yet another laser processing step.

FIG. 17 is a cross-sectional view illustrating a further peeling step.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

A wafer production method of the present embodiment includes a bonded wafer forming method of forming a bonded wafer including a first wafer and a second wafer and a peeling method of peeling the second wafer from the bonded wafer.

### Bonded Wafer Forming Method; Preparation Step

The following describes the bonded wafer forming method.

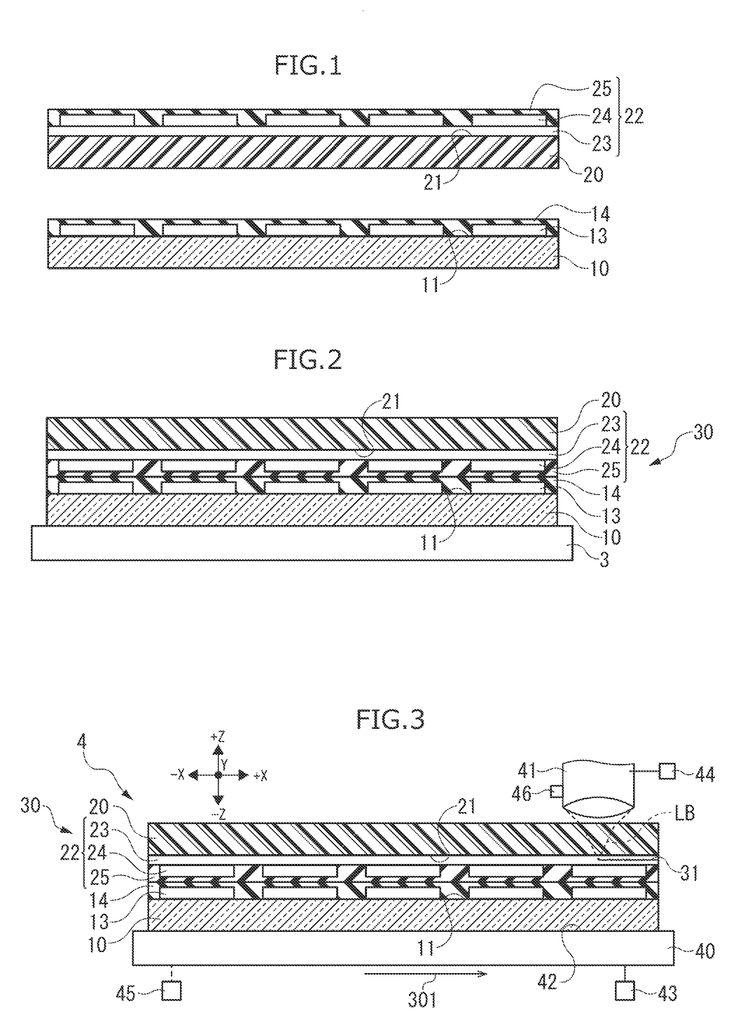

In the bonded wafer forming method, to begin with, a preparation step is performed. In this step, as shown in FIG. 1, a first wafer 10 and a second wafer 20 are prepared.

The first wafer 10 is a wafer made of, for example, silicon or glass. On a surface 11 of the first wafer 10, plural first devices 13 and a first bonding film (SiO₂ film) 14 covering the first devices 13 are formed.

The second wafer 20 is a wafer made of, for example, silicon. The second wafer 20 has a second bonding film 22 provided on its surface 21, and a part of the second bonding film 22 is an SiCN film (second insulating film) 23.

The second bonding film 22 includes the SiCN film 23 formed over the entire surface 21 of the second wafer 20, plural second devices 24 formed on the SiCN film 23, and a first insulating film (SiO₂ film) 25 formed on the SiCN film 23 to cover the second devices 24. In an example shown in FIG. 1, the second devices 24 are formed (stacked) on the surface of the SiCN film 23.

### Bonded Wafer Forming Method; Wafer Bonding Step

After the preparation step, a wafer bonding step is performed. In this step, as shown in FIG. 2, the surface 11 of the first wafer 10 on which the first devices 13 are formed on the surface 11 is bonded to the surface 21 of the second wafer 20 via the first bonding film 14 formed on the surface 11 of the first wafer 10 and the second bonding film 22 formed on the surface 21 of the second wafer 20. As a result, a bonded wafer 30 is formed.

To be more specific, as shown in FIG. 2, to the surface 11 of the first wafer 10 placed on a bonding table 3, the surface 21 side (the side on which the second bonding film 22 is provided) of the second wafer 20 is bonded.

In this regard, for example, the first bonding film 14 of the first wafer 10 is bonded to the first insulating film 25 of the second bonding film 22 of the second wafer 20 by plasma-activated bonding (surface-activated bonding) which is direct bonding. That is to say, the surfaces of the first bonding film 14 and the first insulating film 25 are activated by application of plasma of rare gas, and these surfaces are pressed onto each other, with the result that the first bonding film 14 and the first insulating film 25 are bonded to each other.

In this way, the first wafer 10 and the second wafer 20 are bonded to each other via the first bonding film 14 and the second bonding film 22, and the bonded wafer 30 is formed (produced).

As such, the bonded wafer 30 includes the first wafer 10 in which the first devices 13 and the first bonding film 14 are formed on the surface 11 and the second wafer 20 in which the second bonding film 22 is formed on the surface 21, the surfaces of the first wafer 10 and the second wafer 20 are bonded to each other via the first bonding film 14 and the second bonding film 22, and the second bonding film 22 includes the SiCN film 23 formed on the surface 21 of the second wafer 20 and the second devices 24 formed on the SiCN film 23.

The above-described bonding table 3 may be a below-described chuck table 40 (see FIG. 3) of a laser processor 4.

### Peeling Method: Laser Processing Step

The following describes a peeling method performed for the bonded wafer 30. This peeling method is a method of peeling the second wafer 20 from the first wafer 10 (bonded wafer 30) while keeping the second devices 24 of the second wafer 20 to be remained in the first wafer 10.

In the peeling method, to begin with, a laser processing step is performed. In this step, a processing layer is formed in the SiCN film 23 by applying laser light which has a wavelength transmissive through the second wafer 20 to the bonded wafer 30 from the second wafer 20 side.

To be more specific, as shown in FIG. 3, an operator or an unillustrated transportation device places the bonded wafer 30 onto a holding surface 42 of the chuck table 40 of the laser processor 4, with the second wafer 20 facing up. Thereafter, as a controller 45 of the laser processor 4 connects the holding surface 42 with a suction source (not illustrated), the first wafer 10 of the bonded wafer 30 is sucked and held by the holding surface 42 of the chuck table 40.

Subsequently, as shown in FIG. 3, the controller 45 provides a laser light emitter 41 of the laser processor 4 above the chuck table 40.

In the laser processor 4, the chuck table 40 and the laser light emitter 41 are relatively movable in a horizontal direction. In the present embodiment, the chuck table 40 is movable in an X-axis direction and rotatable in the horizontal direction by a table moving mechanism 43. The laser light emitter 41 is movable in a Y-axis direction by a laser moving mechanism 44.

The laser light emitter 41 is configured to emit laser light LB having a wavelength transmissive through the second wafer 20. To be more specific, the wavelength of the laser light LB falls within a range of 1064 to 5000 nm, and is, for example, 1342 nm. The range of a dose amount of the laser light LB is, for example, 0.1389 J/mm² or more and 0.7 J/mm² or less.

The controller 45 adjusts the positions of the laser light emitter 41 and the chuck table 40 by the table moving mechanism 43 and the laser moving mechanism 44, while checking the relative positions of the laser light emitter 41 and the bonded wafer 30 by a camera 46. By doing so, the controller 45 places a processing start position of the bonded wafer 30 at a location directly below the laser light emitter 41. Furthermore, the controller 45 performs focus adjustment of the laser light emitter 41 so that the focal point of the laser light LB emitted from the laser light emitter 41 is positioned in the SiCN film 23 of the second bonding film 22 of the second wafer 20 in the bonded wafer 30.

Subsequently, the controller 45 causes the laser light emitter 41 to emit the laser light LB and causes the table moving mechanism 43 to processing-feed the bonded wafer 30 in the X-axis direction so as to move the bonded wafer 30 along the X-axis direction relative to the focal point of the laser light LB as indicated by an arrow 301. The speed of this movement is, for example, 120 mm per second. As a result of this, the laser light LB is applied to the SiCN film 23 along the X-axis direction.

Thereafter, the controller 45 applies the laser light LB to the SiCN film 23 of the bonded wafer 30 along the X-axis direction, while changing the position in the Y-axis direction of the laser light emitter 41 by the laser moving mechanism 44. As a result of this, the laser light LB is applied to the substantially entire surface of the SiCN film 23, and a processing layer (peeling layer) 31 is formed in the SiCN film 23. This processing layer 31 is a layer in which silicon, carbon, and nitrogen are formed as part of the SiCN film 23 is destructed by the application of the laser light LB.

Alternatively, a processing layer 31 may be formed in the SiCN film 23 by applying the laser light LB to the SiCN film 23 in a spiral manner.

### Peeling Method; Peeling Step

After the laser processing step, a peeling step is performed. In this step, the second wafer 20 is peeled from the bonded wafer 30 at the processing layer 31.

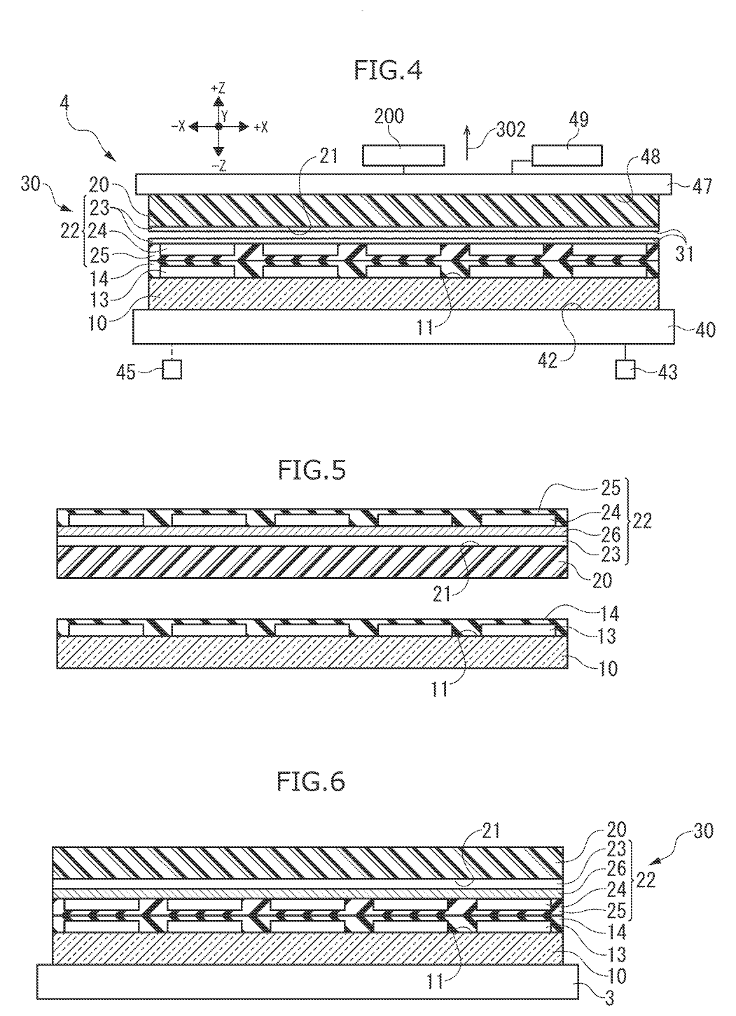

To be more specific, as shown in FIG. 4, the controller 45 controls a moving mechanism 49 to place a sucking table 47 of the laser processor 4 at a location above the chuck table 40, and lower the sucking table 47. As a result, a holding surface 48 that is a lower surface of the sucking table 47 is made contact with the second wafer 20 that is an upper surface of the bonded wafer 30 held on the chuck table 40.

Subsequently, the controller 45 causes the holding surface 48 to communicate with a suction source 200. Due to this, the second wafer 20 is sucked by and held on the holding surface 48 of the sucking table 47. Subsequently, the controller 45 controls the moving mechanism 49 to move up the sucking table 47 as indicated by an arrow 302. As a result, the second wafer 20 is peeled from the bonded wafer 30 (first wafer 10) at the processing layer 31 formed in the SiCN film 23.

Consequently, the second devices 24 are transferred from the second wafer 20 to the first wafer 10, and the first wafer 10 having two types of devices (the first devices 13 and the second devices 24) is produced.

As described above, in the present embodiment, the second bonding film 22 of the second wafer 20 includes the SiCN film 23, and in the laser processing step, as shown in FIG. 3, the processing layer 31 is formed in the SiCN film 23 by the application of the laser light LB to the SiCN film 23. Because the SiCN film 23 absorbs the laser light LB well, the laser light LB does not easily pass through the SiCN film 23. It is therefore possible to suppress the destruction of the second devices 24 and the first devices 13 which are fine pitch layers provided below the SiCN film 23 due to the application of the laser light LB (through light) having passed through the SiCN film 23, without requiring increase in thickness of the SiCN film 23. In other words, it is possible to suppress the destruction of the second devices 24 and the first devices 13 while avoiding deterioration of the productivity due to the increase in thickness of the SiCN film 23.

In the present embodiment, the wavelength of the laser light LB used in the laser processing step falls within a range of 1064 to 5000 nm. The laser light LB having a wavelength falling within this range is transmissive through the second wafer 20 and is easily absorbed by the SiCN film 23. It is therefore possible to further suppress the laser light LB (through light) having passed through the SiCN film 23 without being absorbed by the SiCN film 23 from being applied to the second devices 24.

In addition to the above, in the present embodiment, the range of the dose amount of the laser light LB is 0.1389 J/mm² or more and 0.7 J/mm² or less. In this regard, when the dose amount of the laser light LB increases, even the second wafer 20 which is provided above the target SiCN film 23 and is made of silicon may be damaged by the laser light LB. If the second wafer 20 is damaged, it is necessary to process its surface when the second wafer 20 after the peeling is used again. If the damage of the second wafer 20 is excessive, the second wafer 20 is cracked in the peeling step, and the second wafer 20 may not be easily peeled.

When the dose amount of the laser light LB is too small, it becomes difficult to form stripe-shaped processing layers connected with each other in the SiCN film 23 by the laser light LB. As a result, it becomes difficult to form the processing layer 31 in the entirety of the SiCN film 23, and the second wafer 20 is less likely to be peeled.

In the present embodiment, because the dose amount of the laser light LB is set to fall within the range of 0.1389 J/mm² to 0.7 J/mm², it is possible to form the processing layer 31 in the entirety of the SiCN film 23 by the laser light LB while suppressing damage to the second wafer 20 caused by the laser light LB.

In the wafer production method of the present embodiment, as shown in FIG. 5, the second bonding film 22 of the second wafer 20 may further include a metal film 26 formed between the SiCN film 23 and the second devices 24, in addition to the SiCN film 23, the second devices 24, and the first insulating film 25 described above.

In this configuration, as shown in FIG. 5, in the preparation step of the bonded wafer forming method, a first wafer 10 identical with that shown in FIG. 1 and a second wafer 20 including a metal film 26 are prepared.

Subsequently, in the wafer bonding step of the bonded wafer forming method, as shown in FIG. 6, a surface 11 of the first wafer 10 is bonded to a surface 21 of the second wafer 20 via a first bonding film 14 formed on the surface 11 of the first wafer 10 and a second bonding film 22 formed on the surface 21 of the second wafer 20. To be more specific, as described above with reference to FIG. 3, the first bonding film 14 of the first wafer 10 is bonded to the first insulating film 25 of the second bonding film 22 of the second wafer 20 by, for example, plasma-activated bonding. As a result, a bonded wafer 30 shown in FIG. 6 is formed.

According to the configuration above, the bonded wafer 30 includes the first wafer 10 in which the first bonding film 14 and the first devices 13 are formed on the surface 11 and the second wafer 20 in which the second bonding film 22 is formed on the surface 21, the surfaces of the first wafer 10 and the second wafer 20 are bonded to each other via the first bonding film 14 and the second bonding film 22, and the second bonding film 22 includes the SiCN film 23 formed on the surface 21 of the second wafer 20, the second devices 24 formed on the SiCN film 23, and the metal film 26 formed between the SiCN film 23 and the second devices 24.

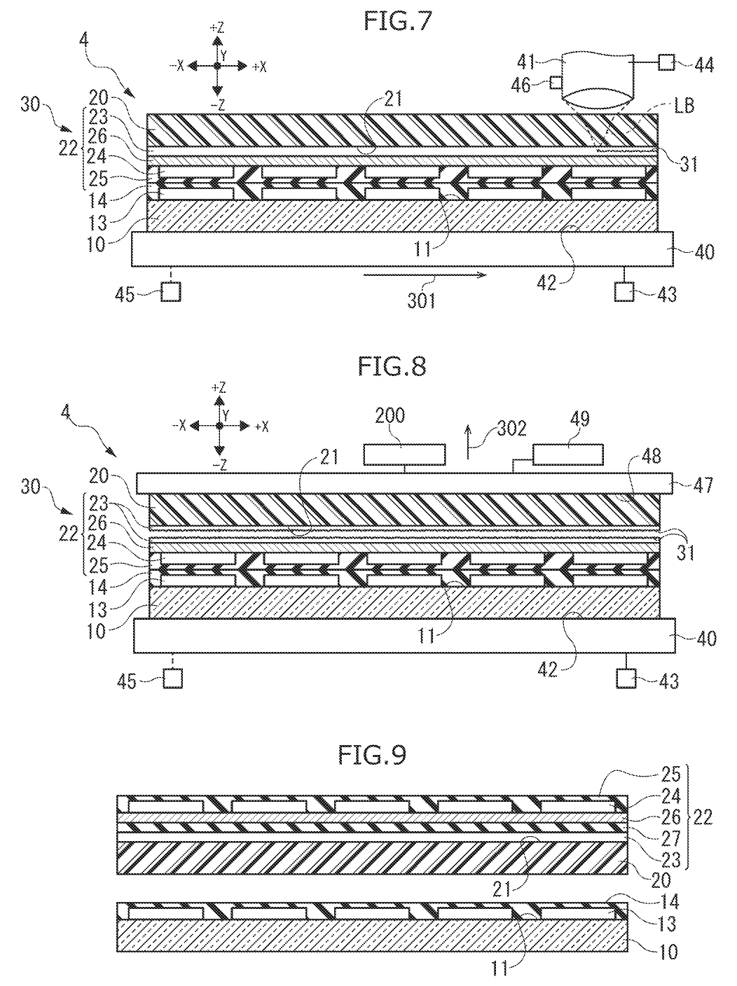

Furthermore, in the laser processing step of the peeling method performed for this bonded wafer 30, in the same manner as in the laser processing step described with reference to FIG. 3, a processing layer 31 is formed in the SiCN film 23 by applying laser light LB which has a wavelength transmissive through the second wafer 20 to the bonded wafer 30 from the second wafer 20 side. That is, as shown in FIG. 7, the laser light LB is applied to the substantially entire surface of the SiCN film 23 of the second wafer 20, and a processing layer 31 is formed in the SiCN film 23.

Thereafter, in the peeling step of the peeling method, the second wafer 20 is peeled from the bonded wafer 30 at the processing layer 31 in the same manner as in the peeling step described with reference to FIG. 4. That is, as shown in FIG. 8, the second wafer 20 is sucked and held by the sucking table 47 of the laser processor 4 and the sucking table 47 is moved up, with the result that the second wafer 20 is peeled from the bonded wafer 30 (first wafer 10) at the processing layer 31 formed in the SiCN film 23.

Due to this, the first wafer 10 having two types of devices (the first devices 13 and the second devices 24) on the surface is produced.

In this configuration, in the laser processing step, the metal film 26 is provided below the SiCN film 23. The laser light LB having passed through the SiCN film 23 can be reflected (shielded) by the metal film 26. It is therefore possible to suppress the laser light LB from being applied to the second devices 24 below the metal film 26.

In the wafer production method of the present embodiment, as shown in FIG. 9, the second bonding film 22 of the second wafer 20 may further include a third insulating film (SiO₂ film or SiN film) 27 formed between the SiCN film 23 and the metal film 26, in addition to the SiCN film 23, the second devices 24, the first insulating film 25, and the metal film 26 described above.

In this configuration, as shown in FIG. 9, in the preparation step of the bonded wafer forming method, a first wafer 10 identical with that shown in FIG. 1 and a second wafer 20 including a metal film 26 and a third insulating film 27 are prepared.

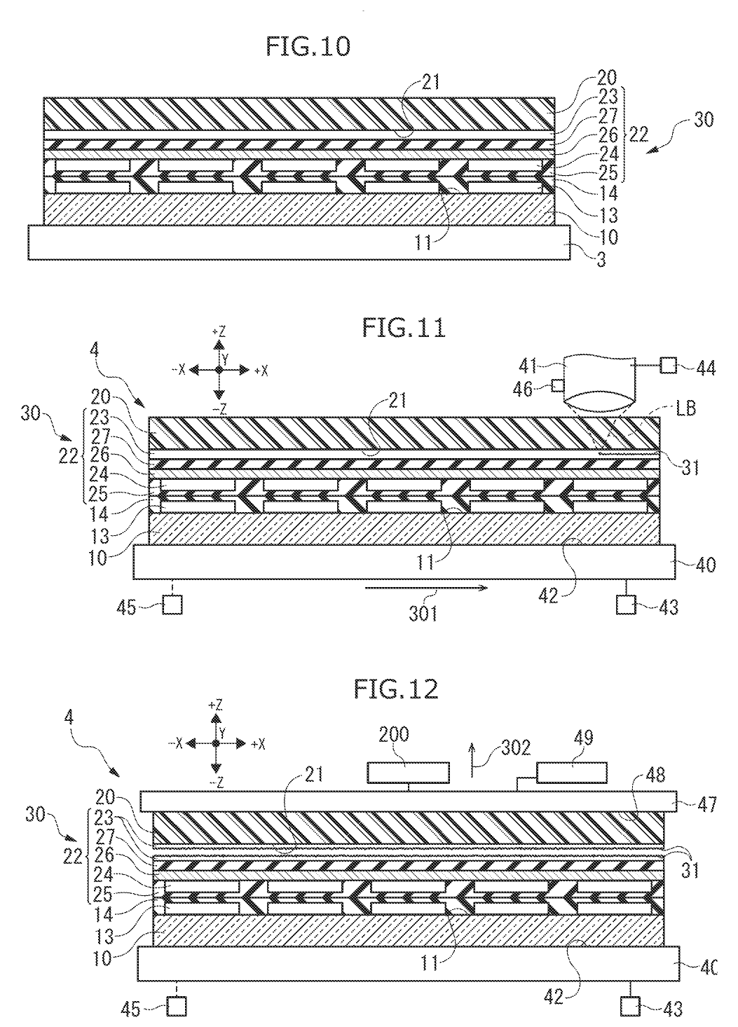

Subsequently, in the wafer bonding step of the bonded wafer forming method, as shown in FIG. 10, a surface 11 of the first wafer 10 is bonded to a surface 21 of the second wafer 20 via a first bonding film 14 formed on the surface 11 of the first wafer 10 and a second bonding film 22 formed on the surface 21 of the second wafer 20. To be more specific, as described above with reference to FIG. 3, the first bonding film 14 of the first wafer 10 is bonded to the first insulating film 25 of the second bonding film 22 of the second wafer 20 by, for example, plasma-activated bonding. As a result, a bonded wafer 30 shown in FIG. 10 is formed.

According to the configuration above, the bonded wafer 30 includes the first wafer 10 in which the first bonding film 14 and the first devices 13 are formed on the surface 11 and the second wafer 20 in which the second bonding film 22 is formed on the surface 21, the surfaces of the first wafer 10 and the second wafer 20 are bonded to each other via the first bonding film 14 and the second bonding film 22, and the second bonding film 22 includes the SiCN film 23 formed on the surface 21 of the second wafer 20, the second devices 24 formed on the SiCN film 23, the metal film 26 formed between the SiCN film 23 and the second devices 24, and the third insulating film 27 (SiO₂ film or SiN film) formed between the SiCN film 23 and the metal film 26.

Furthermore, in the laser processing step of the peeling method performed for this bonded wafer 30, in the same manner as in the laser processing step described with reference to FIG. 3, a processing layer 31 is formed in the SiCN film 23 by applying laser light LB which has a wavelength transmissive through the second wafer 20 to the bonded wafer 30 from the second wafer 20 side. That is, as shown in FIG. 11, the laser light LB is applied to the substantially entire surface of the SiCN film 23 of the second wafer 20, and a processing layer 31 is formed in the SiCN film 23.

Thereafter, in the peeling step of the peeling method, the second wafer 20 is peeled from the bonded wafer 30 at the processing layer 31 in the same manner as in the peeling step described with reference to FIG. 4. That is, as shown in FIG. 12, the second wafer 20 is sucked and held by the sucking table 47 of the laser processor 4 and the sucking table 47 is moved up, with the result that the second wafer 20 is peeled from the bonded wafer 30 (first wafer 10) at the processing layer 31 formed in the SiCN film 23.

Due to this, the first wafer 10 having two types of devices (the first devices 13 and the second devices 24) on the surface is produced.

In this configuration, in the laser processing step, the third insulating film 27 and the metal film 26 are provided in this order below the SiCN film 23. Because the SiCN film 23 and the metal film 26 are separated from each other by the third insulating film 27, it is possible to suppress the heat generated in the SiCN film 23 due to the application of the laser light LB from being transmitted to the metal film 26 side.

In the configuration above, furthermore, the laser light LB having passed through the SiCN film 23 is blocked also by the third insulating film 27. It is therefore possible to suppress the damage of the metal film 26 due to the application of the laser light LB, and to suppress the application of the laser light LB to the second devices 24 and the first devices 13.

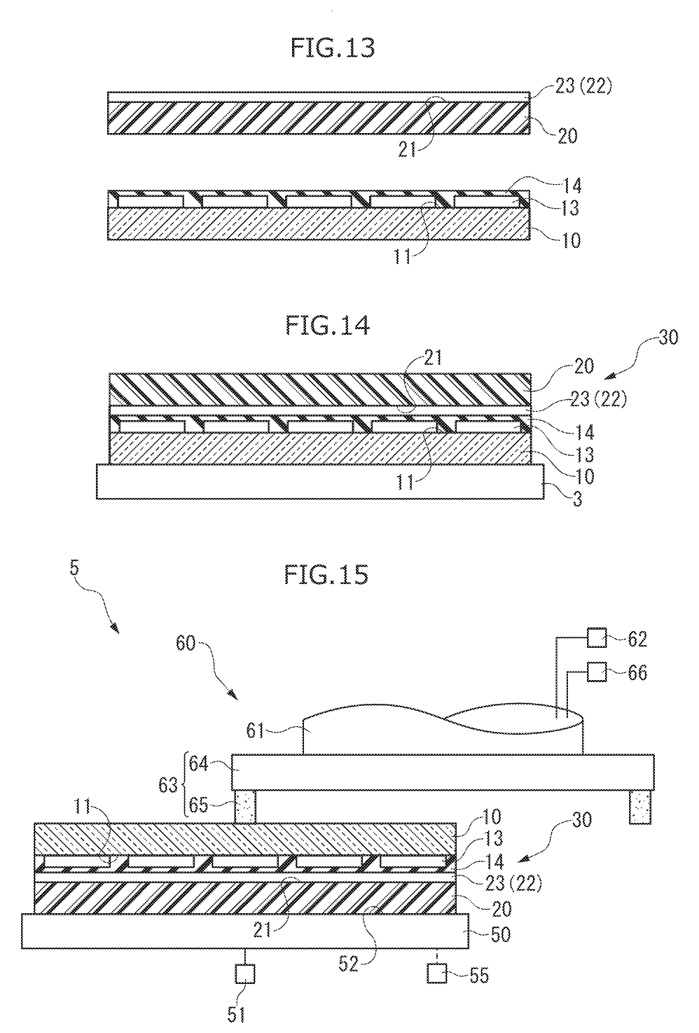

In the wafer production method of the present embodiment, as shown in FIG. 13, the second bonding film 22 of the second wafer 20 may be arranged such that the above-described SiCN film 23 is included but the second devices 24, the first insulating film 25, the metal film 26, and the third insulating film 27 are not included.

In this configuration, as shown in FIG. 13, in the preparation step of the bonded wafer forming method, a first wafer 10 identical with that shown in FIG. 1 and a second wafer 20 including an SiCN film 23 as a second bonding film 22 are prepared.

Subsequently, in the wafer bonding step of the bonded wafer forming method, as shown in FIG. 14, a surface 11 of the first wafer 10 is bonded to a surface 21 of the second wafer 20 via a first bonding film 14 formed on the surface 11 of the first wafer 10 and a second bonding film 22 formed on the surface 21 of the second wafer 20. To be more specific, as described above with reference to FIG. 3, the first bonding film 14 of the first wafer 10 and the SiCN film 23 of the second bonding film 22 of the second wafer 20 are activated by the application of plasma of rare gas, and the surfaces of these films are bonded to each other by plasma-activated bonding. As a result, a bonded wafer 30 shown in FIG. 14 is formed.

According to the configuration above, the bonded wafer 30 includes the first wafer 10 in which the first bonding film 14 and the first devices 13 are formed on the surface 11 and the second wafer 20 in which the second bonding film 22 is formed on the surface 21, the surfaces of the first wafer 10 and the second wafer 20 are bonded to each other via the first bonding film 14 and the second bonding film 22, and the second bonding film 22 includes the SiCN film 23 formed on the surface 21 of the second wafer 20.

In this configuration, the bonded wafer forming method of the wafer production method may include a grinding step (wafer back surface grinding step) described below, as a step performed after the wafer bonding step.

### Bonded Wafer Forming Method; Grinding Step

In this grinding step, the first wafer 10 of the bonded wafer 30 is ground to have a predetermined thickness. To be more specific, as shown in FIG. 15, an operator or an unillustrated transportation device places the bonded wafer 30 onto a holding surface 52 of a chuck table 50 of a grinder 5, with the first wafer 10 facing up. Thereafter, as a controller 55 of the grinder 5 connects the holding surface 52 with a suction source (not illustrated), the second wafer 20 of the bonded wafer 30 is sucked and held by the holding surface 52 of the chuck table 50.

Subsequently, the controller 55 provides a grinding mechanism 60 of the grinder 5 above the chuck table 50. The grinding mechanism 60 includes a spindle 61, a spindle motor 62 configured to rotate the spindle 61, a grinding wheel 63 connected to the lower end of the spindle 61, and an elevation mechanism 66 configured to move up and down the spindle 61. The grinding wheel 63 includes an annular wheel base 64 and grinding stones 65 provided on a lower surface of the wheel base 64.

The controller 55 rotates the chuck table 50 holding the bonded wafer 30 by the rotating mechanism 51 and rotates the spindle 61 and the grinding wheel 63 by the spindle motor 62. Furthermore, the controller 55 lowers the spindle 61 by the elevation mechanism 66 so that the grinding stones 65 of the rotating grinding wheel 63 make contact with the first wafer 10 that is an upper surface of the bonded wafer 30, and grinds the first wafer 10 to have a predetermined thickness.

After this grinding step, the above-described laser processing step of the peeling method is performed. In this laser processing step, in the same manner as in the laser processing step described with reference to FIG. 3, a processing layer 31 is formed in the SiCN film 23 by applying laser light LB which has a wavelength transmissive through the second wafer 20 to the bonded wafer 30 from the second wafer 20 side.

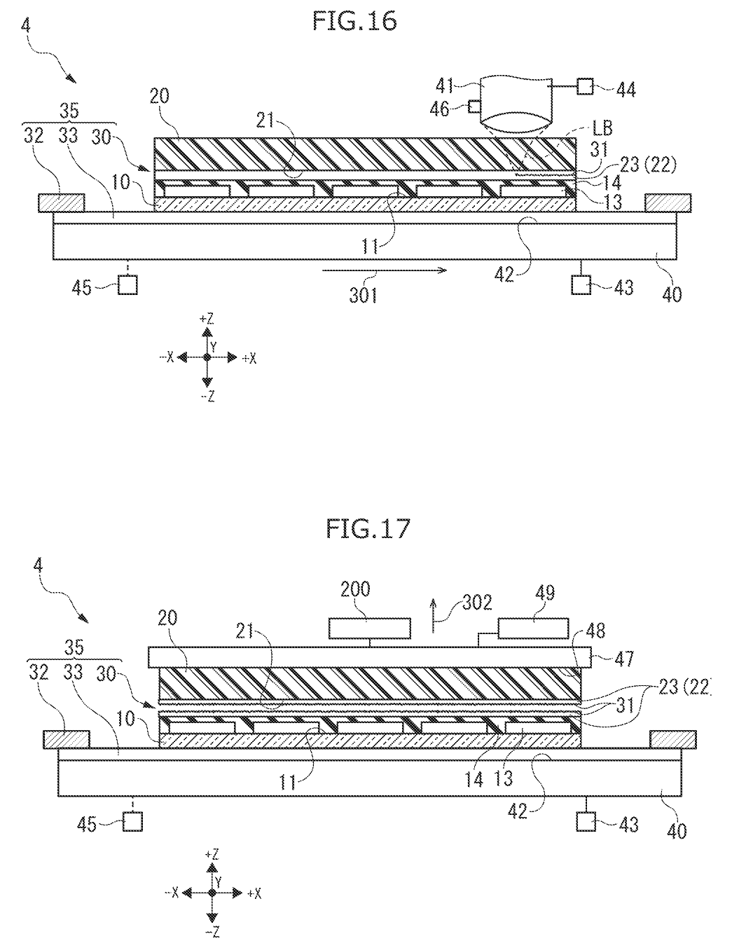

To be more specific, as shown in FIG. 16, an operator or an unillustrated processing apparatus attaches a sheet-shaped supporting tape 33 to the first wafer 10 of the bonded wafer 30 and a back surface of a ring frame 32 that is larger in diameter than the bonded wafer 30. As a result, a work set 35 including the bonded wafer 30 is formed.

Subsequently, an operator or an unillustrated transportation device places the work set 35 onto the holding surface 42 of the chuck table 40 of the laser processor 4, with the second wafer 20 of the bonded wafer 30 facing up.

Then, as described above with reference to FIG. 3, the laser light LB is applied to the substantially entire surface of the SiCN film 23 of the second wafer 20, so that a processing layer 31 is formed in the SiCN film 23.

Thereafter, in the peeling step of the peeling method, the second wafer 20 is peeled from the bonded wafer 30 at the processing layer 31 in the same manner as in the peeling step described with reference to FIG. 4. That is, as shown in FIG. 17, the second wafer 20 is sucked and held by the sucking table 47 of the laser processor 4 and the sucking table 47 is moved up, with the result that the second wafer 20 is peeled from the bonded wafer 30 (first wafer 10) at the processing layer 31 formed in the SiCN film 23.

Consequently, the first wafer 10 including the first devices 13 and having the predetermined thickness is produced.

According to this configuration, in the laser processing step, the processing layer 31 is formed in the SiCN film 23 by applying the laser light LB to the SiCN film 23. As described above, the laser light LB does not easily pass through the SiCN film 23. It is therefore possible to suppress the destruction of the first devices 13 provided below the SiCN film 23 due to the application of the laser light LB.

In the present embodiment, the wafer production method includes the bonded wafer forming method of forming a bonded wafer including a first wafer and a second wafer and the peeling method of peeling the second wafer from the bonded wafer. In this regard, in the wafer production method, the above-described peeling method may be performed for an already-existing bonded wafer, without forming a bonded wafer. In other words, the wafer production method may be differently arranged on condition that a step of preparing a bonded wafer including a first wafer and a second wafer and execution of the above-described peeling method for this bonded wafer are included. The step of preparing a bonded wafer encompasses, for example, formation of a bonded wafer and acquisition of a bonded wafer having already been formed.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A peeling method comprising:
a laser processing step of forming a processing layer in an SiCN film by applying, to a bonded wafer which includes a first wafer and a second wafer and in which a surface of the first wafer in which a first device and a first bonding film are formed on the surface is bonded to a surface of the second wafer in which a second bonding film including the SiCN film is formed on the surface via the first bonding film and the second bonding film, laser light having a wavelength transmissive to the second wafer from the second wafer side; and
a peeling step of peeling the second wafer from the bonded wafer at the processing layer.

2. The peeling method according to claim 1, wherein, the second bonding film of the second wafer includes a second device formed on the SiCN film.

3. The peeling method according to claim 2, wherein, the second bonding film of the second wafer includes a metal film formed between the SiCN film and the second device.

4. The peeling method according to claim 3, wherein, the second bonding film of the second wafer includes an SiO₂ film or an SiN film formed between the SiCN film and the metal film.

5. The peeling method according to claim 1, wherein, the wavelength of the laser light falls within a range of 1064 to 5000 nm, and a range of a dose amount of the laser light is 0.1389 J/mm² or more and 0.7 J/mm² or less.

6. A wafer production method comprising:
preparing a bonded wafer which includes a first wafer and a second wafer and in which a surface of the first wafer in which a first device and a first bonding film are formed on the surface is bonded to a surface of the second wafer in which a second bonding film including the SiCN film is formed on the surface via the first bonding film and the second bonding film; and
performing the peeling method according to claim 1 for the bonded wafer.

7. A bonded wafer comprising:
a first wafer in which a first device and a first bonding film are formed on a surface; and
a second wafer in which a second bonding film is formed on a surface,
the surfaces of the first wafer and the second wafer being bonded to each other via the first bonding film and the second bonding film, and
the second bonding film including an SiCN film formed on the surface of the second wafer and a second device formed on the SiCN film.

8. The bonded wafer according to claim 7, wherein, the second bonding film of the second wafer includes a metal film formed between the SiCN film and the second device.

9. The bonded wafer according to claim 8, wherein, the second bonding film of the second wafer includes an SiO₂ film or an SiN film formed between the SiCN film and the metal film.
